(19) United States
(12) Patent Application Publication
(10) Pub. No.: US 2026/0031819 A1
(43) Pub. Date: Jan. 29, 2026

(54) Systems and Methods for a Multi-Mode Programmable IO

(71) Applicant: Altera Corporation, San Jose, CA (US)

(72) Inventors: Chee Hong Aw, Bayan Lepas (MY); Seh Leong Goh, Sungai Ara (MY)

(21) Appl. No.: 19/342,043

(22) Filed: Sep. 26, 2025

(51) Int. Cl. H03K 19/173; H03K 17/08

(52) U.S. Cl. CPC H03K 19/173; H03K 17/08

(57) ABSTRACT

Systems or methods of the present disclosure may provide an integrated circuit system that includes a programmable logic device that includes programmable logic units implementing a user design and programmable input/output (IO) circuitry including multiple receiver instances that include a first type of multiplexer to receive a pad input, a second type of multiplexer to receive a voltage, and a third type of multiplexer to receive a clock. The first type of multiplexer is a high-speed multiplexer that has electrical overstress (EOS) protection, the second type of multiplexer has EOS protection and responds slower than the first type of multiplexer, and the third type of multiplexer does not have EOS protection. The programmable IO circuitry also includes a receiver to selectively receive outputs of the first type of multiplexer, the second type of multiplexer, and the third type of multiplexer at an input of the receiver.

### BACKGROUND

The present disclosure relates generally to integrated circuits, such as field-programmable gate arrays and/or programmable logic devices. More particularly, the present disclosure relates to a programmable input-output (IO).

This section is intended to introduce the reader to various aspects of art that may be related to various aspects of the present disclosure, which are described and/or claimed below. This discussion is believed to be helpful in providing the reader with background information to facilitate a better understanding of the various aspects of the present disclosure. Accordingly, it may be understood that these statements are to be read in this light, and not as admissions of prior art.

Programmable logic devices may be designed and/or programmed to perform a wide variety of operations depending on user designs. As such, using the flexibility of the programmable logic devices, they may be programmed to receive signals using various different IO standards. For instance, the input voltages may be relatively high for some IO standards. The input voltages may be high enough that application of such input voltages to gates of certain transistors (e.g., thin-gate transistors) may make such transistors subject to failure. Instead, higher-power transistors (e.g., thick-gate transistors) may be used. However, the higher power transistors may be unable to support higher speeds due to the limitations of the thicker gates.

### BRIEF DESCRIPTION OF THE DRAWINGS

Various aspects of this disclosure may be better understood upon reading the following detailed description and upon reference to the drawings in which:

FIG. 1 is a block diagram of a system used to program an integrated circuit system, in accordance with an embodiment of the present disclosure;

FIG. 2 is a block diagram of an example integrated circuit system of FIG. 1 with programmable IO, in accordance with an embodiment of the present disclosure;

FIG. 3 is a block diagram of a portion of the programmable IO of FIG. 2 using transmission gates, in accordance with an embodiment of the present disclosure;

FIG. 4 is a circuit diagram of an example transmission gate of FIG. 3 with thick-gate transistors, in accordance with an embodiment of the present disclosure;

FIG. 5 is a block diagram of a portion of the programmable IO of FIG. 2 using high-speed protected multiplexers, protected multiplexers, and variable supply multiplexers, in accordance with an embodiment of the present disclosure;

FIG. 6 is a circuit diagram of a supply multiplexer that may be used by the high-speed protected multiplexers, protected multiplexers, and/or variable supply multiplexers of FIG. 5 using transmission gates, in accordance with an embodiment of the present disclosure;

FIG. 7 is a circuit diagram of the high-speed protected multiplexer of FIG. 5, in accordance with an embodiment of the present disclosure;

FIG. 8 is a circuit diagram of the protected multiplexer of FIG. 5, in accordance with an embodiment of the present disclosure;

FIG. 9 is a circuit diagram of the variable supply multiplexer of FIG. 5, in accordance with an embodiment of the present disclosure;

FIG. 10 is a block diagram of a portion of the programmable IO of FIG. 2 using an inter-pin communication that can be used in ViX testing; and

FIG. 11 is a block diagram of a data processing system including the integrated circuit system of FIG. 1, in accordance with an embodiment of the present disclosure.

### DETAILED DESCRIPTION OF SPECIFIC EMBODIMENTS

One or more specific embodiments will be described below. In an effort to provide a concise description of these embodiments, not all features of an actual implementation are described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the phrase A “based on” B is intended to mean that A is at least partially based on B. Moreover, the term “or” is intended to be inclusive (e.g., logical OR) and not exclusive (e.g., logical XOR). In other words, the phrase A “or” B is intended to mean A, B, or both A and B.

As previously noted, transmission gates may be susceptible to electrical overstress (EOS), especially when the input to the transmission gate may exceed voltage ratings of the transistors forming the transmission gate. As previously noted, thick-gate transistors may be unsuitable for transmission gates in receivers that may demand higher-speed/faster response than thick-gate transistors can provide. Instead, thin-gate transistors are to be used. However, these thin-gate transistors cannot be stacked on the input path without impacting throughput/responsiveness. As such, at least some of the multiplexers of a pad multiplexer (padmux) may be high-speed and EOS protected, at least some others are lower speed but also EOS protected, and others are not EOS protected since they would not be exposed to the pad of the receiver that may encounter voltages outside of permissible voltage levels. This heterogeneous mix of multiplexers in the padmux may support higher IO speeds by using the thin-gate transistors with higher bandwidth to replace conventional thick-gate input padmuxes. Thin-gate transistors are cheaper than thick-gate transistors enabling a cost savings in fabrication of integrated circuit devices. The heterogeneous mix of multiplexers also are configurable to support different modes for the receiver (RX) to enable a single RX to perform multiple functions without implementing multiple instances of each RX dedicated to a specific function. As noted below, the configurable padmux enables Non-Touch Leakage (NTL) and voltage input (ViX) testing with fewer external components demanded.

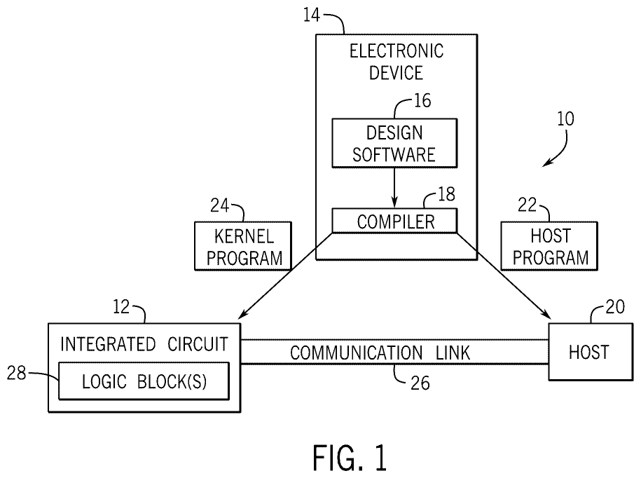

With the foregoing in mind, FIG. 1 illustrates a block diagram of a system 10 that may implement one or more designs on an integrated circuit system 12 (e.g., a single monolithic integrated circuit or a multi-die system of integrated circuits) to perform a wide variety of operations. The integrated circuit system 12 may include a single integrated circuit, multiple integrated circuits in a package, or multiple integrated circuits in multiple packages communicating remotely (e.g., via wires or traces). In some cases, the designer (e.g., user) may specify a high-level program to be implemented, such as an OPENCL® program that may enable the designer to more efficiently and easily provide programming instructions to configure a set of programmable logic cells for the integrated circuit system 12 without specific knowledge of low-level hardware description languages (e.g., Verilog, very high-speed integrated circuit hardware description language (VHDL)). For example, since OPENCL® is quite similar to other high-level programming languages, such as C++, designers of programmable logic familiar with such programming languages may have a reduced learning curve in comparison to designers that are unfamiliar with low-level hardware description languages to implement new functionalities in the integrated circuit system 12.

The integrated circuit system 12 may include a field-programmable gate array (FPGA) (e.g., Agilex™, Stratix®, Arria®, MAX®, or Cyclone® devices by Altera® Corporation). In a configuration mode of the integrated circuit system 12, a designer may use an electronic device 14 (e.g., a computer) to implement high-level designs (e.g., a system user design) using design software 16, such as a version of Quartus Design Suite® by Altera Corporation. The electronic device 14 may use the design software 16 and a compiler 18 to convert the high-level program into a lower-level description (e.g., a configuration program, a bitstream). The compiler 18 may provide machine-readable instructions representative of the high-level program to a host 20 and the integrated circuit system 12. The design software 16 may include a design tool that generates graphical user interfaces (GUIs) with different views of a design that may be implemented onto the FPGA, for example. The design tool may also provide design context and/or trade-off information associated with the design, as further described herein.

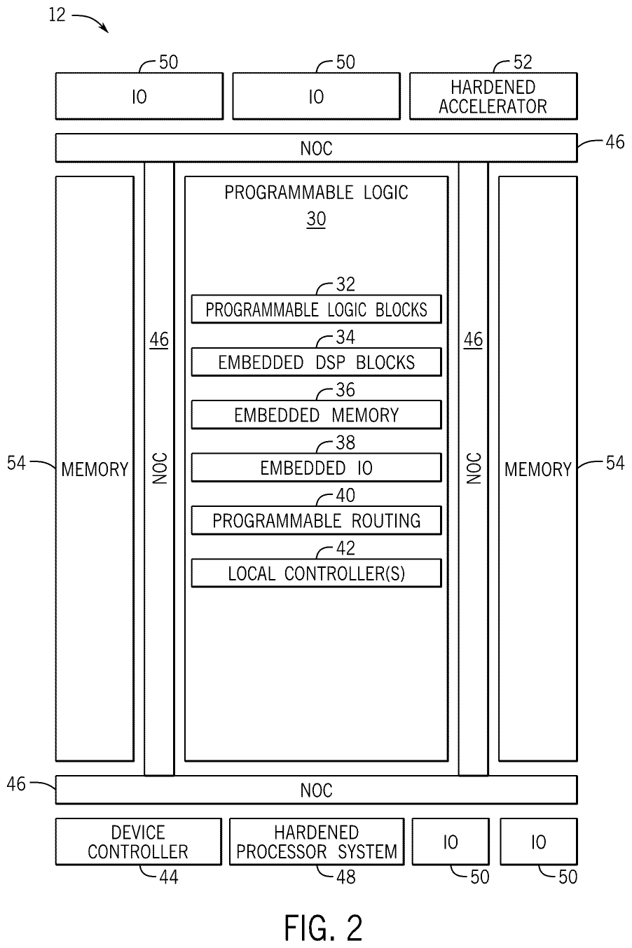

The host 20 may receive a host program 22 that may control or be implemented by a kernel program 24. To implement the host program 22, the host 20 may communicate instructions from the host program 22 to the integrated circuit system 12 via a communication link 26 that may include, for example, direct memory access (DMA) communications or peripheral component interconnect express (PCIe) communications. As will be described in greater detail below in FIG. 2, in some embodiments, the kernel program 24 and the host 20 may enable configuration of a logic block 28 on the integrated circuit system 12. The logic block 28 may include circuitry and/or other logic elements and may be configurable to implement a variety of functions in combination with digital signal processing (DSP) blocks.

The designer may use the design software 16 to generate and/or to specify a low-level program, such as the low-level hardware description languages described above. Further, in some embodiments, the system 10 may be implemented without the host program 22. Thus, embodiments described herein are intended to be illustrative and not limiting.

The integrated circuit system 12 may take any suitable form that may implement the data processing system 14. In one example shown in FIG. 2, the integrated circuit system 12 may include programmable logic circuitry 30, which may include a two-dimensional array of many different functional blocks, such as programmable logic blocks 32, embedded digital signal processing (DSP) blocks 34, embedded memory blocks 36, and embedded input-output blocks 38. In many cases, there may be rows or columns of these functional blocks that may be programmably connected to one another using programmable routing 40.

The programmable logic blocks 32 may be programmed to implement a wide variety of logic circuitry. The programmable logic blocks 32 may include a number of adaptive logic modules (ALMs), which may take the form of lookup tables (LUTs) that can be programmed to implement a logic truth table, effectively enabling any of the programmable logic blocks 32 to implement any desired logic circuitry when configured with the system design configuration 14. The programmable logic blocks 32 and are sometimes referred to as logic array blocks (LABs) or configurable logic blocks (CLBs) that are used to build processing elements (PEs) that are arranged in an SA or an ACU. Each PE in the systolic array computes a partial result as a function of data from its upstream neighbors, stores the partial result, and passes it downstream to the next PE.

The embedded DSP blocks 34, embedded memory blocks 36, and embedded IO blocks 38 may be distributed around the programmable logic blocks 32. For example, there may be several columns of programmable logic blocks 32 for every column of DSP blocks 34, column of embedded memory blocks 36, or column of embedded IO blocks 38.

The embedded DSP blocks 34 may include “hardened” circuits that are specialized to efficiently perform certain arithmetic operations. This is in contrast to “soft logic” circuits that may be programmed into the programmable logic blocks 32 to perform the same functions, but which may not be as efficient as the hardened circuits of the DSP blocks 34. The embedded memory blocks 36 may include dedicated local memory (e.g., blocks of 20 kB, blocks of 1 MB, blocks of 4 MB, etc.). The embedded memory blocks 36 may be implemented using dual-port DRAM (DPRAM) or single-port DRAM (SPDRAM). Additionally or alternatively, the embedded memory blocks 36 may be implemented as SRAM.

The embedded IO blocks 38 may allow for inter-die or inter-package communication. The embedded DSP blocks 34, embedded memory blocks 36, and embedded IO blocks 38 may be accessible to the programmable logic blocks 32 using the programmable routing 40. The embedded IO blocks 38 may be programmable (along with the programmable routing 40) to enable appropriate communication for various different circuit designs including different routing, different voltages, different frequencies, and the like.

The various functional blocks of the programmable logic circuitry 30 may be grouped into programmable regions, sometimes referred to as logic sectors, that may be individually managed and configured by corresponding local controllers 42 (e.g., sometimes referred to as Local Sector Managers (LSMs)). The grouping of the programmable logic circuitry 30 resources on the integrated circuit system 12 into logic sectors, logic array blocks, logic elements, or adaptive logic modules is merely illustrative. In general, the integrated circuit system 12 may include functional logic blocks of any suitable size and type, which may be organized in accordance with any suitable logic resource hierarchy. Indeed, there may be other functional blocks (e.g., other embedded application specific integrated circuit (ASIC) blocks) than those shown in FIG. 2.

Before continuing, it may be noted that the programmable logic circuitry 30 of the integrated circuit system 12 may be controlled by programmable memory elements sometimes referred to as configuration random access memory (CRAM). Memory elements may be loaded with configuration data (also called programming data or a configuration bitstream) that represents the system design configuration 16. Once loaded, the memory elements may provide a corresponding static control signal that controls the operation of an associated functional block. In one scenario, the outputs of the loaded memory elements are applied to the gates of metal-oxide-semiconductor transistors in a functional block to turn certain transistors on or off and thereby configure the logic in the functional block including the routing paths. Programmable logic circuit elements that may be controlled in this way include parts of multiplexers (e.g., multiplexers used for forming routing paths in interconnect circuits), look-up tables, logic arrays, AND, OR, NAND, and NOR logic gates, pass gates, and the like. The configuration memory elements may use any suitable volatile and/or non-volatile memory structures such as random-access-memory (RAM) cells, fuses, antifuses, programmable read-only-memory (ROM) memory cells, mask-programmed, laser-programmed structures, or combinations of structures such as these.

A device controller 44, sometimes referred to as a secure device manager (SDM), may manage the operation of the integrated circuit system 12. The device controller 44 may include any suitable logic circuitry to control and/or program the programmable logic circuitry 30 or other elements of the integrated circuit system 12. For example, the device controller 44 may include a processor (e.g., an x86 processor or a reduced instruction set computer (RISC) processor, such as an Advanced RISC Machine (ARM) processor or a RISC-V processor) that executes instructions stored on any suitable tangible, non-transitory, machine-readable media (e.g., memory or storage). Additionally or alternatively, the device controller 44 may include a hardware finite state machine (FSM). The device controller 44 may provide other functions, such as serving as a platform for virtual machines that may manage the operation of the integrated circuit system 12.

A network-on-chip (NOC) 46 may connect the various elements of the integrated circuit system 12. The NOC 46 may provide rapid, packetized communication to and from the programmable logic circuitry 30 and other blocks, such as a hardened processor system 48, input/output (I/O) blocks 50, a hardened accelerator 52, and local device memory 54. The integrated circuit system 12 may include the hardened processor system 48 when the integrated circuit system 12 takes the form of a system-on-chip (SOC). The hardened processor system 48 may include a hardened processor (e.g., an x86 processor or a reduced instruction set computer (RISC) processor, such as an Advanced RISC Machine (ARM) processor or a RISC-V processor) that may act as a host machine on the integrated circuit system 12. The I/O blocks 50 may enable communication using any suitable communication protocol(s) with other devices outside of the integrated circuit system 12, such as a separate memory device. The hardened accelerator 52 may include any hardened application-specific integrated circuitry (ASIC) logic to perform a desired acceleration function. For example, the hardened accelerator 52 may include hardened circuitry to perform cryptographic or media encoding or decoding. The memory 54 may provide local device memory (e.g., cache) that may be readily accessible by the programmable logic circuitry 30.

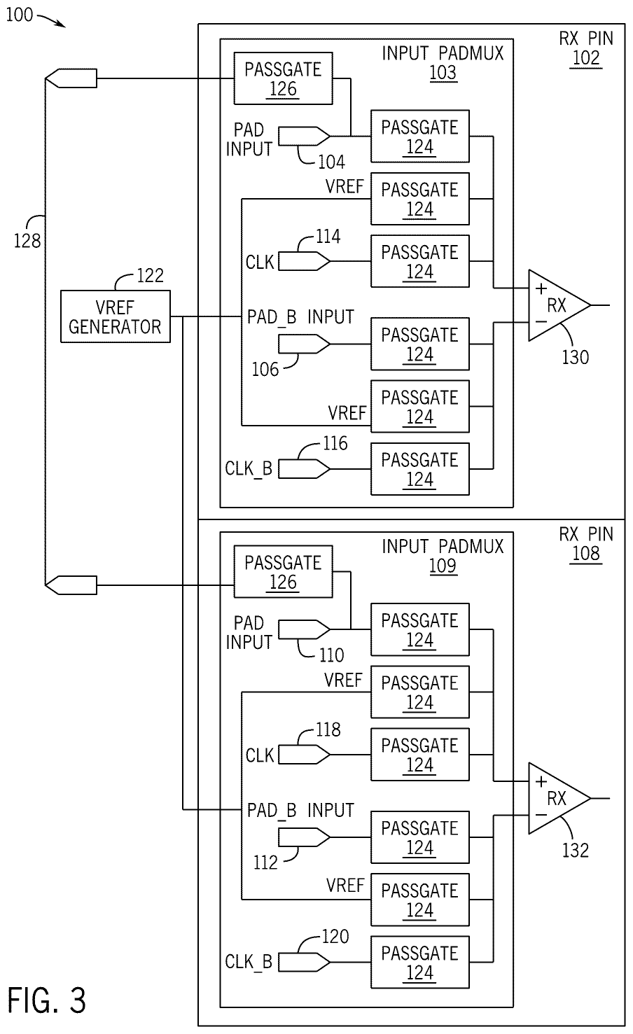

FIG. 3 is a block diagram of a portion 100 of the embedded IO blocks 38 that includes a first receiver (RX) pin 102 having a padmux 103 used to select routing inputs to a receiver 130. The padmux 103 selectively transmits signals from a first pad 104 and a first bar pad 106 to the receiver 130. The first bar pad 106 may be used to receive a complementary signal than that received at the first pad 104 to enable complementary signaling. The portion 100 also includes a second RX pin 108 having a padmux 109 used to select routing inputs to a receiver 132. The padmux 109 selectively transmits signals from a second pad 110 and a second bar pad 112. The second bar pad 112 may be used to receive a complementary signal than that received at the second pad 110 to enable complementary signaling. Although two RX pins with related pads are shown for simplicity, the embedded IO blocks 38 may include any number of RX pins with related pads. Indeed, the embedded IO blocks 38 may include tens, hundreds, or thousands of RX pins with related pads. In some embodiments, these RX pins may be grouped into common groups (e.g., pairs, 13 RX pints, etc.) that enable connections/shorts between pads of the RX pins.

The input padmux 103 also receives a clock (Clk) 114 and a clock bar (Clk_b) 116. The clock 114 and the clock bar 116 may be complementary with each other. The input padmux 109 also receives a clock 118 and a clock bar 120. The clock 118 and the clock bar 120 may be complementary with each other. The input padmux 103 and the input padmux 109 may also receive a reference voltage (Vref) from a Vref generator 122.

The receivers 130 and 132 are capable of receiving signals from respective pads 104 and 110, respective clocks 114 and 118, and Vref from the Vref generator 122 at a first input (e.g., non-inverting/positive input). Likewise, the receivers 130 and 132 are capable of receiving signals from respective pad bars 106 and 112, respective clock bars 116 and 120, and Vref from the Vref generator 122 at a second input (e.g., inverting/negative input). To select which of these possible inputs are to be received at the inputs of the receivers 130 and 132, the padmuxes 103 and 109 include passgates 124 that selectively enable these signals to be transmitted to the first inputs of the respective receivers 130 and 132. For instance, when the receiver 130 is to receive the input from the pad 104 at its first input, a passgate 124 is used to enable the pad to be connected to the first input of the receiver 130 while other passgates 124 block connection of the first input of the receiver 130 to Vref and the clock 116. Similarly, if the second input of the receiver 130 is to receive the clock bar 116, a corresponding passgate 124 between the clock bar 116 and the receiver 130 enables transmission of the clock bar 116 to the second input of the receiver 130 while other passgates 124 block connection of the second input of the receiver 130 to Vref and the second bar pad 106.

In some situations, signals received at one pad of one receiver pin may be used by a receiver of an adjacent receiver pin. For instance, the receiver 130 may receive a signal from the second pad 110. To enable this connection, inter-pin passgates 126 may selectively enable the connection between adjacent pads via an inter-pin path 128. As such, when the inter-pin passgates 126 are both enabled, the pads of the RX pin 102 and the RX pin 108 are tied together.

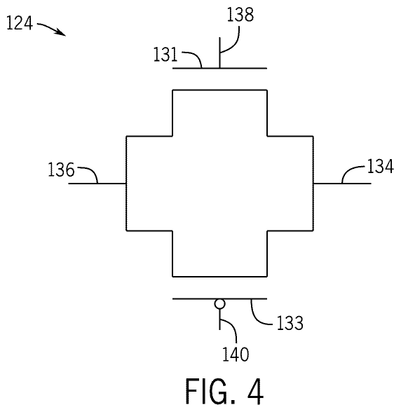

FIG. 4 is a circuit diagram of an example embodiment of a passgate 124. The inter-pin passgates 126 may be implemented similarly to the passgates 124. In the illustrated embodiment of the passgates 124, the passgates 124 include complementary metal oxide semiconductors (CMOS) that include transistors 131 and 133. These transistors are complementary. For instance, the transistor 131 may be a n-type metal oxide semiconductor (NMOS), and the transistor 133 may be a p-type metal oxide semiconductor (PMOS). The transistor 131 may enable current flow through the passgate 124 from passgate node 134 to passgate node 136 when a control signal 138 is asserted (e.g., logic high). The control signal 138 is an NMOS select signal used to transmit through the transistor 131. Similarly, the transistor 133 may enable current flow through the passgate 124 from passgate node 136 to passgate node 134 when a control signal 140 is asserted (e.g., logic low for a bar signal). The control signal 140 is a PMOS select signal used to transmit through the transistor 133. The control signal 138 and the control signal 140 may be complementary with each other. As illustrated, the transistors 131 and 133 may be thick-gate transistors that support high-voltage IO standards. For example, Mobile Industry Processor Interface (MIPI) D-PHY Low-Power Receiver (LPRX) IO standard input can swing up to 1.3V, Low Voltage Complementary Metal-Oxide-Semiconductor (LVCMOS) IO standard that is non-terminated and may have an overshoot over 1.1V, DDR5 operates with a 1.1V supply, and/or other IO standards.

Thick-gate transistors (e.g., transistors with gate oxide thicknesses of 3-5 nm in 180 nm process) have robust electrical overstress (EOS) limits (e.g., ˜1.8V). Thus, using thick-gate transistors in the passgates is sufficient to prevent EOS without additional EOS protection mechanisms. However, thick-gate transistors are bandwidth limited. Thus, including any thick-gate transistors may inherently hamper bandwidth below permissible levels. However, if non-thick-gate/thin-gate transistors (e.g., gate oxide thickness smaller than that of thick-gate transistors (e.g., <3 nm in 180 nm process)) are used, EOS becomes a concern for passgates. Accordingly, EOS-protected passgates are to be used in such situations to ensure that the thin-gate transistors are always operating within safe voltage regions even for IO standards that have high input voltages that are higher than the thin-gate junction voltage limit.

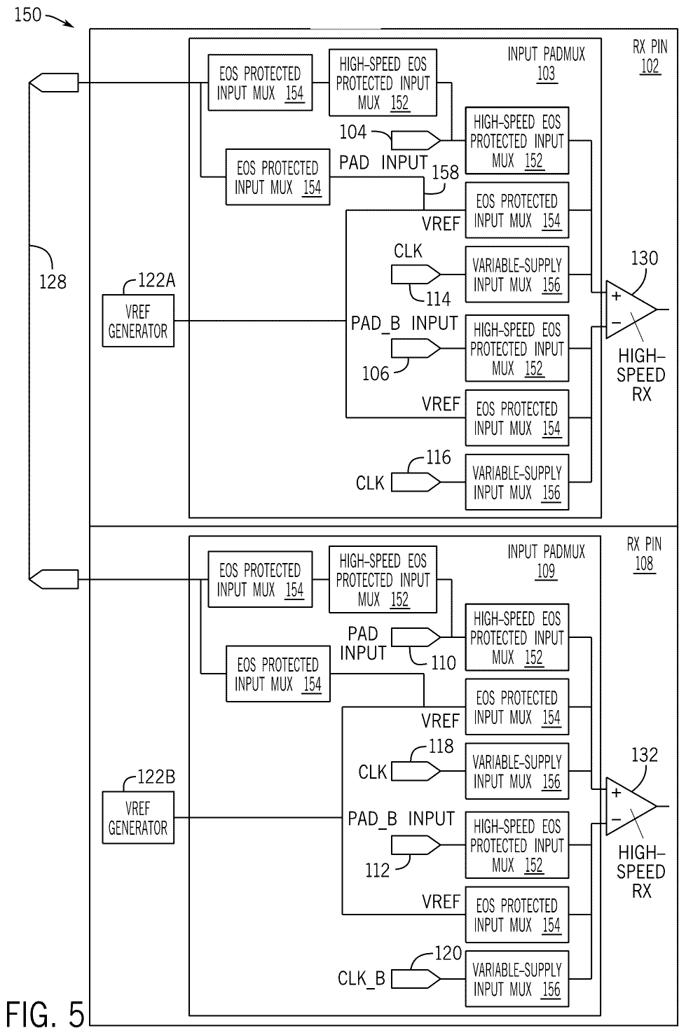

FIG. 5 is a block diagram of a portion 150 of an embodiment of the embedded IO blocks 38 that includes the first receiver (RX) pin 102 having the padmux 103 used to select routing inputs to the receiver 130 and the second receiver (RX) pin 108 having the padmux 109 used to select routing inputs to the receiver 132. The portion 150 is similar to the portion 100 of FIG. 3 except that the portion 150 includes High-speed EOS-protected input multiplexers (HSPMs) 152, EOS-protected input multiplexers (PMs) 154, and variable-supply input multiplexers (VSMs) 156 in place of the passgates (also called transmission gates herein) 124 that use thick-gate transistors. Each of the HSPMs 152, PMs 154, and VSMs 156 will be discussed in more detail below, and each is used to replace a thick-gate transistor-based passgate 124 depending on what signals they are gating. Furthermore, the inter-pin passgates 126 may be replaced with both an HSPM 152 and a PM 154.

Additionally, in the portion 150, each RX pin 102 and 108 includes its own Vref generator 122 (individually referred to as Vref generator 122A and 122B). These separate Vref generators 122 enable generating different reference voltages in the different RX pins. Moreover, as illustrated, new paths 158 and 160 may be added to be used for debugging modes, test modes, and/or other operations that enable a locally generated Vref (e.g., from Vref generator 122A) to be shared with other RX pins (e.g., RX pin 108) via the inter-pin path 128.

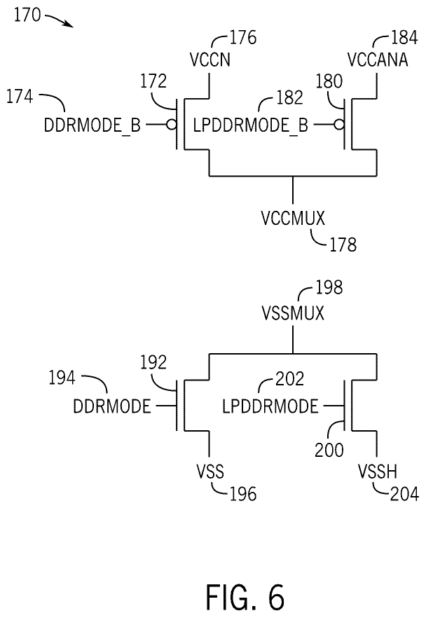

FIG. 6 is a schematic diagram of a supply multiplexer 170 that may be used to control what voltages are used within the HSPMs 152, the PMs 154, and/or the VSMs 156. As illustrated, the supply multiplexer 170 includes a transistor 172 (e.g., PMOS) that is configured to receive a control signal 174 (e.g., DDRMODE_B) to control whether VCCN 176 (˜1.1V) is to be used by the connected multiplexer(s) as VCCMUX 178 based on whether the control signal 174 is asserted. Similarly, the supply multiplexer 170 includes a transistor 180 (e.g., PMOS) that is configured to receive another control signal 182 (e.g., LPDDRMODE_B) to control whether VCCANA 184 (e.g., ˜0.75V) is to be used by the connected multiplexer(s) as the VCCMUX 178 based on whether the control signal 182 is asserted. For instance, as illustrated, if a DDRMODE is turned on, the control signal 174 (e.g., DDRMODE_B) is asserted as a logic low causing VCCMUX 178 to be equal to VCCN 176. However, if a low power DDR mode is to be deployed by instead asserting the control signal 182 (e.g., LPDDRMODE_B) to cause VCCMUX 178 to be equal to VCCANA 184 that is smaller than VCCN 176 and intermediate between VCCN 176 and VSS 196.

The supply multiplexer 170 also includes a transistor 192 (e.g., NMOS) that is configured to receive a control signal 194 (e.g., DDRMODE) to control whether VSS 196 is to be used by the connected multiplexer(s) as VSSMUX 198 based on whether the control signal 194 is asserted. Similarly, the supply multiplexer 170 includes a transistor 200 (e.g., NMOS) that is configured to receive another control signal 202 (e.g., LPDDRMODE) to control whether VSSH 204 is to be used by the connected multiplexer(s) as the VSSMUX 198 based on whether the control signal 202 is asserted. For instance, as illustrated, if a DDRMODE is turned on, the control signal 194 (e.g., DDRMODE) is asserted as a logic high causing VSSMUX 198 to be equal to VSS 196. However, if a low power DDR mode is to be deployed by instead asserting the control signal 202 (e.g., LPDDRMODE) to cause VSSMUX 198 to be equal to VSSH 204 that is an elevated “ground” (e.g., VCCN−0.9V) that is intermediate between VCCANA 184 and VSS 196.

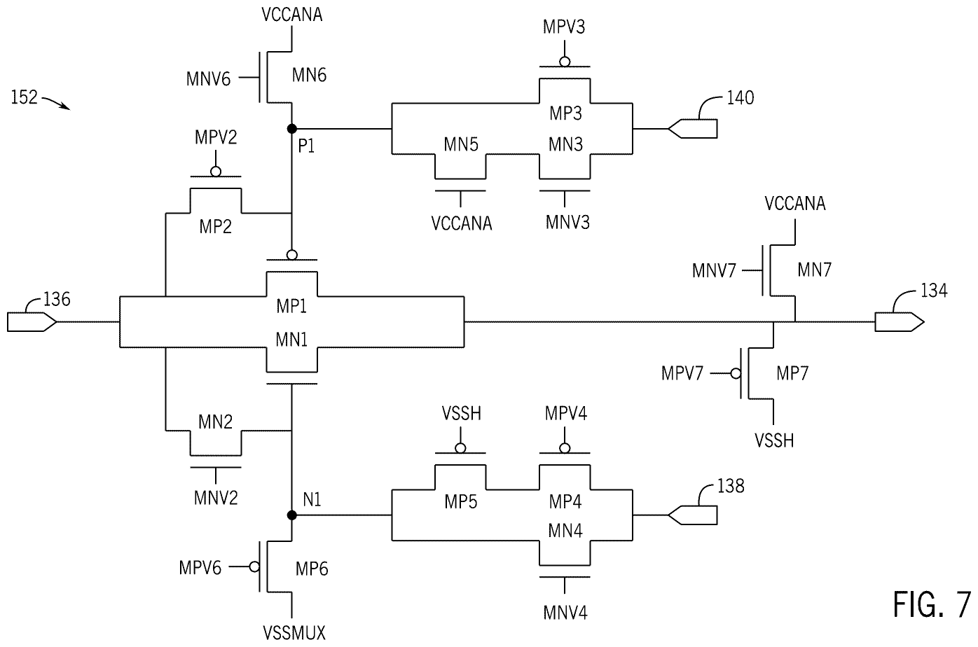

FIG. 7 is a circuit diagram of an embodiment of the HSPM 152. As illustrated, the HSPM 152 includes transistors MP1 and MN1 that function similar to the transistors 132 and 130 of FIG. 4 passing signals from an input (e.g., node 136) to an output (e.g., node 134). However, to provide functionality at a higher bandwidth, the transistors MP1 and MN1 are not thick-gate transistors. Accordingly, the HSPM 152 includes additional EOS protection for the transistors MP1 and MN1.

For instance, the illustrated embodiment of the HSPM 152 includes transistors MP2 and MN2. MP2 is coupled between the input and a gate of the transistor MP1, and MN2 is coupled between the input and a gate of the transistor MN1. MP2 has its gate tied to a voltage MPV2 that is set according to a mode of operation for the HSPM 152, as discussed below. Similarly, MN2 has its gate tied to a voltage MNV2 that is set according to the mode of operation.

The HSPM 152 also includes a transistor MP3 (PMOS) that is coupled between the gate of MP1 and the control signal 140. The gate of MP3 is coupled to voltage MPV3 that has a value set by the selected mode for the HSPM 152. The HSPM 152 also includes transistors MN3 (NMOS) and MN5 (NMOS) between the gate of MP1 and the control signal 140. The gate of MN3 is coupled to voltage MNV3 that has a value set by the selected mode for the HSPM 152. The gate of MN5 is coupled to VCCANA. The HSPM 152 further includes a transistor MN6 (NMOS) that is coupled between the gate of MP1 and VCCANA. A gate of MN6 is coupled to a voltage MNV6 that has a value set by the selected mode for the HSPM 152.

The HSPM 152 includes a transistor MN4 (NMOS) that is coupled between the gate of MN1 and the control signal 138. The gate of MN4 is coupled to voltage MNV4 that has a value set by the selected mode for the HSPM 152. The HSPM 152 also includes transistors MP4 (PMOS) and MP5 (PMOS) between the gate of MN1 and the control signal 138. The gate of MP4 is coupled to voltage MPV4 that has a value set by the selected mode for the HSPM 152. The gate of MP5 is coupled to VSSH. The HSPM 152 further includes a transistor MP6 (PMOS) that is coupled between the gate of MN1 and VSSMUX. A gate of MP6 is coupled to a voltage MPV6 that has a value set by the selected mode for the HSPM 152.

The HSPM 152 also includes a transistor MN7 (NMOS) coupled between VCCANA and the node 134 and also includes a transistor MP7 (PMOS) coupled between VSSH and the node 134. The gate of MN7 receives a voltage MNV7 that is set by a selected mode for the HSPM 152, and the gate of MP7 receives a voltage MPV7 that is set by a selected mode for the HSPM 152.

As previously noted, the path from an input pad (at node 136) to a receiver (at node 134) may demand wide bandwidth to run at high speed with little attenuation on the signal. Additionally, this path should tolerate voltages higher than thin-gate transistor EOS limits due to IO standards voltages and/or due to overshoot/undershoot during general purpose IO (GPIO) modes. These 2 demands are often conflicting or exclusionary since high-speed demands use low-impedance paths, but higher EOS tolerances normally use transistor stacking (i.e., high impedance) to step down the voltage for protection.

As illustrated above, in a protection mode, the HSPM 152 overcomes these challenges using thin-gate transistors. As such, the HSPM 152 provides EOS protection blocking overshoot and undershoot from the pad input. In summary, MP1 and MN1 are thin-gate transistors that are the input transmission gate without stacking transistors in the input path that would interfere with high bandwidth. The remaining transistors are in the HSPM 152 for EOS protection, when in a protection mode. Such EOS protection may be disabled in the HSPM 152 in a normal/non-protected mode.

### HSPM Protection Mode of Operation

In the protection mode, protection is applied when the receiver (e.g., receiver 130) and its input padmux are not used. This configuration puts all the transistors in safe conditions without exposure to voltages higher than EOS limits. This protects the circuit from EOS when there is overshoot and undershoot happening during GPIO modes while the corresponding receiver is not in use. This also shuts off the input path from a respective pad to the respective receiver.

To enable the protection mode, the gate voltages MPV3, MNV3, MPV4, and MNV4 disable the respective transistors from connecting the control signals 140 and 138 to the gates of MP1 and MN1. For instance, in the protection mode, MPV3 and MPV4 are both set to VCCMUX to switch off MP3 and MP4, and MN3V and MN4V are set to VSSMUX to switch off MN3V and MN4V.

Also in the protection mode, the gate voltages MP2V and MN2V are set to VCCANA. This voltage level at the gates of MP2 and MN2 protects MP1 and MN1 from overshoot and/or undershoot. Even with the pad voltage swings from low to high or there is overshoot or undershoot, the voltage at node P1 is always greater than VCCANA (e.g., ˜0.75V) protecting MP1 from EOS. Similarly, node N1 is always less than VCCANA. The remaining transistors are connected where they are not exposed to EOS. In summary, the connections of MP2 and MN2 between the node 136 and the transmission gates MP1 and MN1 ensure that MP1 and MN1 are always shut off when the protection mode is enabled.

MN7 and MP7 have their gate voltages MNV7 and MPV7 tied to VCCANA. MN7 and MP7 are bleed/leaker transistors that ensure that the node voltage of node 134 is always around the level of VCCANA.

### HSPM Normal Mode of Operation

Normal mode is for operation when a respective receiver and input padmux are being used. The gate voltages MPV3, MNV3, MPV4, and MNV4 turn on the respective devices, MP3, MN3, MP4, and MN4. For instance, MPV3 and MPV4 are set to VSSMUX to switch on MP3 and MP4. Likewise, MNV3 and MNV4 are set to VCCMUX to switch on MN3 and MN4. Turning on these transistors connects the control signal 140 to the gate of MP1 and connects the control signal 138 to the gate of MN1 thereby enabling the control signals 138 and 140 to control whether the HSPM 152 is transmitting from the node 136 to the node 134. The transistors for EOS protection (i.e., MP2, MN2, MP6, MN6, MP7, and MN7) are all turned off. For example, in the normal mode, MPV2, MPV6, and MPV7 are all set to VCCMUX to turn off MP2, MP6, and MP7. Likewise, in the normal mode, MNV2, MNV6, and MNV7 are all set to VSSMUX to turn off MN2, MN6, and MN7. With EOS turned off, the HSPM 152 acts as a normal transmission gate.

### PM Operation

A PM 154 is different from the HSPM 152 where the PM 154 is for a static input signal, such as a reference voltage that does not demand a high bandwidth, but the voltage may still vary from 0 to VCCN that may be greater than an EOS limit of the transistors. Thus, a simpler EOS multiplexer may be used that is less complicated and/or smaller than the HSPM 152.

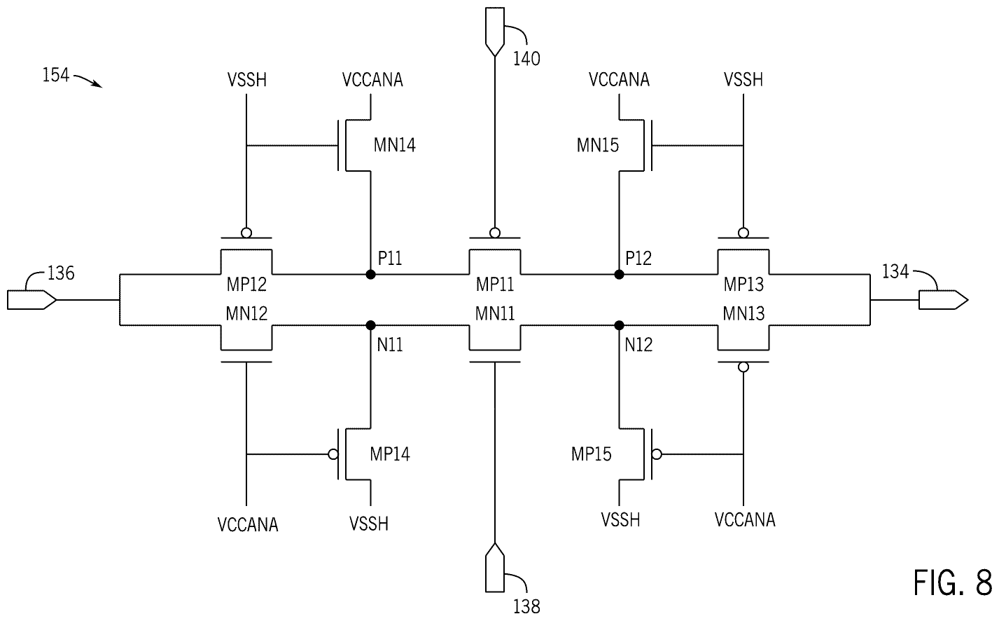

As illustrated in FIG. 8, the PM 154 receives an input (e.g., at node 136) and selectively outputs the input (e.g., at note 134) based on control signals 138 and 140. To this means, the PM 154 includes transistors MP11 (PMOS) and MN11 (NMOS) as transmission gates that have their gates tied to the respective control signals 140 and 138. The PM 154 also includes a transistor MP12 (PMOS) between MP11 and the node 136. The transistors MP12 and MP11 are coupled together at node P11. Also, the PM 154 includes a transistor MN12 (NMOS) between MN11 and the node 136. The transistors MN12 and MN11 are coupled together at node N11.

Similarly, the PM 154 includes a transistor MP13 (PMOS) between MP11 and the node 134. The transistors MP13 and MP11 are coupled together at node P12. Likewise, the PM 154 includes a transistor MN13 (NMOS) between MN11 and the node 134. The transistors MN13 and MN11 are coupled together at node N12.

Furthermore, the PM 154 includes a transistor MN14 (NMOS) coupled between the node P11 and VCCANA. A gate of MN14 is tied to the gate of MP12 and tied to VSSH. Similarly, the PM 154 includes a transistor MN15 (NMOS) coupled between the node P12 and VCCANA with the gate of MN15 and the gate of MP13 each tied to VSSH.

Moreover, the PM 154 includes a transistor MP14 (PMOS) coupled between the node N11 and VSSH. A gate of MP14 is tied to the gate of MN12 and tied to VCCANA. Similarly, the PM 154 includes a transistor MP15 (PMOS) coupled between the node N12 and VSSH with the gate of MP15 and the gate of MN13 each tied to VCCANA.

As previously noted, MP11 and MN11 are a transmission gate while MP12, MN12, MP13, MN13, MP14, MN14, MP15, and MN15 provide EOS protection for the transmission gate. In operation, MP12, MN14, MN15, and MP14 ensure that the voltage of the nodes P11 and P12 is no lower than VSSH and that the voltage level remains between VSSH and VCCN. Similarly, MN12, MP14, MP15, and MN14 ensure that the voltage of the nodes N11 and N12 will exceed VCCANA and that the voltage remains between VSS and VCCANA. The regulation of the voltage protects all of the transistors from EOS even while the signal at the input (e.g., node 136) and the output (e.g., node 134) can swing between VSS and VCCN that may exceed EOS limitations without MP12, MN12, MP13, MN13, MP14, MN14, MP15, and MN15.

### VSM Operation

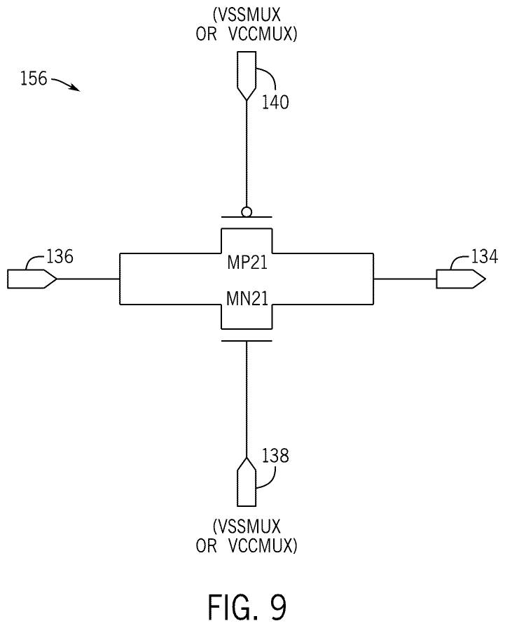

As illustrated in FIG. 9, the VSM 156 is similar to the transmission gate 124 of FIG. 4 with the transistor 133 instead with a thin-film based transistor MP21 and the transistor 131 instead as a thin-film based transistor MN21. The VSM 156 is not connected to any respective input pads that may carry relatively high voltages. Therefore, the VSM 156 may omit EOS protection even when using thin-film transistors MP21 and MN21. Another difference with the VSM 156 from the transmission gate 124 is that it utilizes the supply multiplexer 170 to provide the control signals 138 and 140 as select signals that may be switched between different supplies. For example, during a DDRMODE as indicated by the control signal (DDRMODE) 194 and the control bar signal 174 (DDRMODE_B) being asserted in the supply multiplexer 170, the supply multiplexer 170 transmits the control signal 140 as VCCN 176 and the control signal 138 as VSSH 204. Likewise, during a LPDDRMODE as indicated by the control signal (LPDDRMODE) 202 and the control bar signal (LPDDRMODE_B) 182 being asserted in the supply multiplexer 170, the supply multiplexer 170 transmits the control signal 140 as VCCANA 184 and the control signal 138 as VSS 196. This configuration with different supply voltages ensures that the transmission gate implemented using MP21 and MN21 can pass through high-speed AC-coupled clock (Clk or Clk_b) with little attenuation and with no EOS exposure.

### Training Modes

Together, the three types of multiplexer circuits pass through different types of signals during the different functional modes. Furthermore, the portion 150 also enables training modes, such as offset calibrations and delay compensations. Offset calibrations may be performed by transmitting different reference voltages from different RX pins to a same receiver and comparing the differences. Delay compensations may be performed by sending a true clock (e.g., Clk 114) and a bar/complementary clock (e.g., Clk_b 116) to a receiver (e.g., receiver 130) to determine delays in the routing.

### Silicon Debug Training Mode

Analog signals like those on the pad inputs (e.g., Pad input 104) and Vref within an RX instance/pin may be multiplexed together, shorted with an analog multiplexer output from other RX instance, routed to an analog observation pin. This routing enables monitoring the analog signal on the silicon by selecting the relevant multiplexer(s).

### Non-Touched Test Mode

As previously noted, the analog multiplex outputs of different RX pins may be connected together. This connection may be used for a Non-Touched Leakage (NTL) test in which analog multiplexers inside two different RX pins are turned on at the same time to check the IO pin leakage and undergo voltage input/output (ViX/VoX) testing.

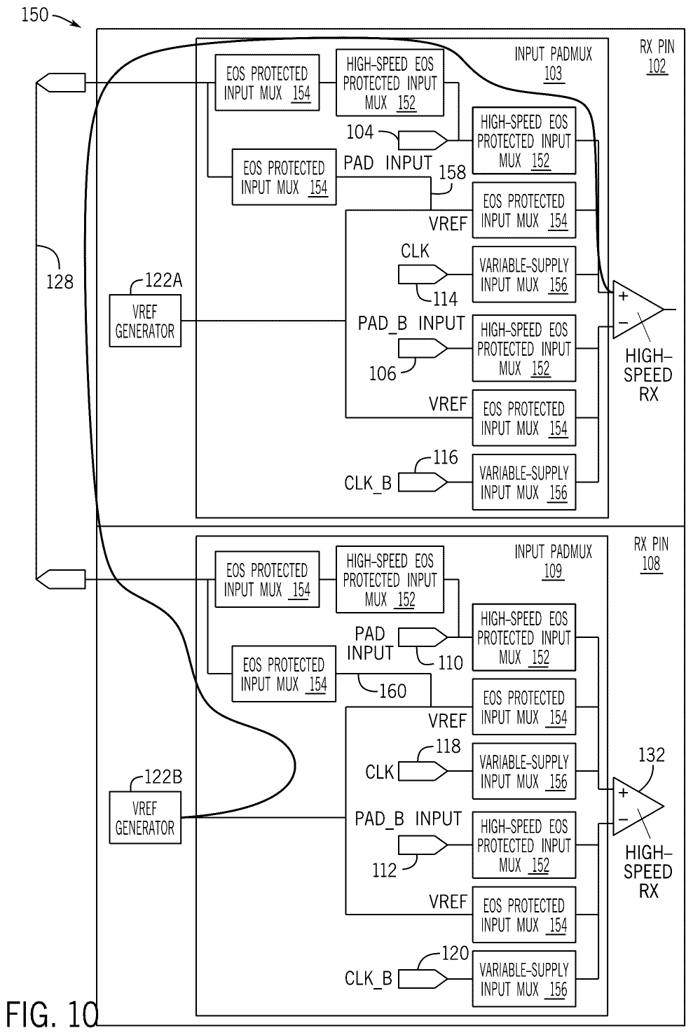

The interconnection (e.g., inter-pin path 128) also enables the Vref generated by adjacent RX to be utilized to perform ViX testing. For example, as illustrated in FIG. 10, the Vref from the Vref generator 122B of the RX pin 108 may be connected to the receiver 130 of the RX pin 102 via route 250 from the Vref generator 122B to the receiver 130. Together with the internal Vref (e.g., from Vref generator 122A) within the RX pin 102, there are two different reference voltages that can be utilized to check the voltage input high (Vih) and the voltage input low (Vil) of the RX pin 102. One Vref is held constant while the other Vref is stepped through until the RX circuit output from the receiver 130 trips to check the input transition voltage. As illustrated, the route 250 traverses the inter-pin path 128, two instances of PMs 154, and two instances of HSPMs 152 between the Vref generator 122B and the non-inverting input of the receiver 130. The route from the Vref generator 122A traverses a single PM 154 on the way to the inverting input of the receiver 130. By providing this interconnection, production test setup can be simplified to save test cost and provide more accuracy. Without the interconnection through analog multiplexers, ViX testing will either demand the input voltage from the tester or the voltage from additional Vref generator in the RX pin being testing that would take up additional resources on the integrated circuit system 12. Alternatively, a TX driver may generate the reference voltage and depend upon resistance compensation that adjusts for resistance variation across die process and temperature thereby adding complexity to the ViX testing. This additional compensation increased test time and resulted in greater step size error than the inter-die connection-based ViX testing.

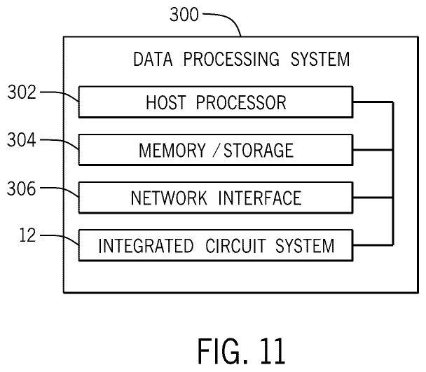

The processes discussed above may be carried out on the integrated circuit system 12, which may be a component included in a data processing system, such as a data processing system 300, shown in FIG. 11. The data processing system 300 may include the integrated circuit system 12 (e.g., a programmable logic device), a host processor 302, memory and/or storage circuitry 304, and a network interface 306. The data processing system 300 may include more or fewer components (e.g., electronic display, user interface structures, application specific integrated circuits (ASICs)). The host processor 302 may include any of the foregoing processors that may manage a data processing request for the data processing system 300 (e.g., to perform elaboration and simulation, to perform encryption, decryption, machine learning, video processing, voice recognition, image recognition, data compression, database search ranking, bioinformatics, network security pattern identification, spatial navigation, cryptocurrency operations, or the like). The memory and/or storage circuitry 304 may include random access memory (RAM), read-only memory (ROM), one or more hard drives, flash memory, or the like. The memory and/or storage circuitry 304 may hold data to be processed by the data processing system 300. In some cases, the memory and/or storage circuitry 304 may also store configuration programs (e.g., bitstreams, mapping function) for programming the integrated circuit system 12. The network interface 306 may allow the data processing system 300 to communicate with other electronic devices. The data processing system 300 may include several different packages or may be contained within a single package on a single package substrate. For example, components of the data processing system 300 may be located on several different packages at one location (e.g., a data center) or multiple locations. In another example, components of the data processing system 300 may be located in separate geographic locations or areas, such as cities, states, or countries.

The data processing system 300 may be part of a data center that processes a variety of different requests. For example, the data processing system 300 may receive a data processing request via the network interface 306 to perform encryption, decryption, machine learning, video processing, voice recognition, image recognition, data compression, database search ranking, bioinformatics, network security pattern identification, spatial navigation, digital signal processing, or other specialized tasks.

The techniques and methods described herein may be applied with other types of integrated circuit systems. To provide only a few examples, these may be used with central processing units (CPUs), graphics cards, hard drives, or other components.

While the embodiments set forth in the present disclosure may be susceptible to various modifications and alternative forms, specific embodiments have been shown by way of example in the drawings and have been described in detail herein. However, it should be understood that the disclosure is not intended to be limited to the particular forms disclosed. The disclosure is to cover all modifications, equivalents, and alternatives falling within the spirit and scope of the disclosure as defined by the following appended claims.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function] . . . ” or “step for [perform]ing [a function] . . . ”, it is intended that such elements are to be interpreted under 35 U.S.C. 112(f). However, for any claims containing elements designated in any other manner, it is intended that such elements are not to be interpreted under 35 U.S.C. 112(f).

### EXAMPLE EMBODIMENTS

EXAMPLE EMBODIMENT 1. An integrated circuit system, comprising:
a programmable logic device, comprising:
programmable logic units implementing a user design; and
programmable input/output (IO) circuitry comprising a plurality of receiver instances each comprising:
a first type of multiplexer, wherein the first type of multiplexer is configured to receive a pad input, and the first type of multiplexer is a high-speed multiplexer that has electrical overstress (EOS) protection;
a second type of multiplexer that has EOS protection and is configured to receive a voltage, wherein the second type of multiplexer responds slower than the first type of multiplexer;
a third type of multiplexer that does not have EOS protection and is configured to receive a clock; and
a receiver to selectively receive outputs of the first type of multiplexer, the second type of multiplexer, and the third type of multiplexer at an input of the receiver.

EXAMPLE EMBODIMENT 2. The integrated circuit system of example embodiment 1, wherein the programmable IO circuitry comprises a pad multiplexer (padmux) that includes the first type of multiplexer, the second type of multiplexer, and the third type of multiplexer.

EXAMPLE EMBODIMENT 3. The integrated circuit system of example embodiment 1, wherein the programmable IO circuitry comprises a reference voltage generator to generate a reference voltage as the voltage.

EXAMPLE EMBODIMENT 4. The integrated circuit system of example embodiment 1, wherein the programmable IO circuitry comprises:
a second copy of the first type of multiplexer to receive a second pad input;
a second copy of the second type of multiplexer to receiver a second voltage; and
a third copy of the third type of multiplexer to receive a second clock.

EXAMPLE EMBODIMENT 5. The integrated circuit system of example embodiment 4, wherein the receiver comprises a non-inverting input to selectively receive the pad input, the voltage, and the clock.

EXAMPLE EMBODIMENT 6. The integrated circuit system of example embodiment 5, wherein the receive comprises an inverting input to selectively receive the second pad input, the second voltage, and the second clock.

EXAMPLE EMBODIMENT 7. The integrated circuit system of example embodiment 6, wherein second pad input is a bar pad input that receives a signal complementary to that received at the pad input.

EXAMPLE EMBODIMENT 8. The integrated circuit system of example embodiment 1, wherein the programmable IO comprises a supply mux that selectively outputs variable supply voltages based a selected mode.

EXAMPLE EMBODIMENT 9. The integrated circuit system of example embodiment 8, wherein the third type of multiplexer is to receive the variable supply voltages as control signals to a transmission gate of the third type of multiplexer.

EXAMPLE EMBODIMENT 9. The integrated circuit system of example embodiment 8, wherein the selected mode comprises an indication of whether to use a low power mode or a regular power mode.

EXAMPLE EMBODIMENT 10. The integrated circuit system of example embodiment 9, wherein the low power mode comprises a LPDDRMODE and the regular power mode comprises a DDRMODE.

EXAMPLE EMBODIMENT 11. The integrated circuit system of example embodiment 1, wherein the first type of multiplexer comprises pair of transistors acting as transmission gate as the only transistors between an input node and an output node of the first type of multiplexer.

EXAMPLE EMBODIMENT 12. The integrated circuit system of example embodiment 11, wherein the first type of multiplexer comprises a plurality of EOS protection transistors that provide EOS protection without inhibiting transmission through the transmission gate.

EXAMPLE EMBODIMENT 13. The integrated circuit system of example embodiment 12, wherein the plurality of EOS protection transistors comprises a first set of transistors coupled between an input node the first type of multiplexer and gates of the transistors of the transmission gate to protect the transistors of the transmission gate from EOS.

EXAMPLE EMBODIMENT 14. The integrated circuit system of example embodiment 13, wherein the plurality of EOS protection transistors comprises a second set of transistors coupled between control signals and gate terminals of the transistors of the transmission gate to manage a voltage at nodes at the gate terminals of the transistors of the transmission gate.

EXAMPLE EMBODIMENT 15. The integrated circuit system of example embodiment 14, wherein the plurality of EOS protection transistors comprises a set of leaker transistors coupled to the output node of the first type of multiplexer to limit a voltage on the output node.

EXAMPLE EMBODIMENT 16. A programmable input/output (IO) for a programmable logic device, wherein the programmable IO comprises:
a first receiver (RX) instance, comprising:
a receiver;
a first pad input to receive first pad signals from a first pad;
a first clock input to receive a first clock signal;
a first reference voltage input to receive a first reference voltage;
a first multiplexer configured to receive the first pad signals and selectively output the first pad signals to the receiver, wherein the first multiplexer comprise a first transmission gate and first electrical overstress (EOS) protection transistors;
a second multiplexer to receive the first reference voltage and selectively output the first reference voltage to the receiver, wherein the second multiplexer comprises a second transmission gate and second EOS protection transistors, wherein the second multiplexer has a lower bandwidth than the first multiplexer; and
a third multiplexer to receive the first clock signal and selectively output the first clock signal to the receiver.

EXAMPLE EMBODIMENT 17. The programmable IO of example embodiment 16, wherein the receiver comprises an inverting input and a non-inverting input, the receiver is to receive the first pad signals, the first clock signal, and the first reference voltage at the non-inverting input, and the first RX instance comprises:
a second pad input to receive second pad signals from a second pad;
a second clock input to receive a second clock signal;
a second reference voltage input to receive a second reference voltage;
a fourth multiplexer configured to receive the second pad signals and selectively output the second pad signals to the inverting input of the receiver, wherein the fourth multiplexer comprises a third transmission gate and third electrical overstress (EOS) protection transistors;
a fifth multiplexer to receive the second reference voltage and selectively output the second reference voltage to the inverting input of the receiver, wherein the fifth multiplexer comprises a fourth transmission gate and second EOS protection transistors, wherein the fifth multiplexer has a lower bandwidth than the fourth multiplexer; and
a sixth multiplexer to receive the second clock signal and selectively output the second clock signal to the inverting input of the receiver.

EXAMPLE EMBODIMENT 18. The programmable IO of example embodiment 16, comprising a second RX instance comprising:
a second receiver;
a second pad input to receive second pad signals from a second pad;
a second clock input to receive a second clock signal;
a second reference voltage input to receive a second reference voltage;
a fourth multiplexer configured to receive the second pad signals and selectively output the second pad signals to the second receiver, wherein the fourth multiplexer comprises a third transmission gate and third electrical overstress (EOS) protection transistors;
a fifth multiplexer to receive the second reference voltage and selectively output the second reference voltage to the second receiver, wherein the fifth multiplexer comprises a fourth transmission gate and second EOS protection transistors, wherein the fifth multiplexer has a lower bandwidth than the fourth multiplexer; and
a sixth multiplexer to receive the second clock signal and selectively output the second clock signal to the second receiver.

EXAMPLE EMBODIMENT 19. The programmable IO of example embodiment 18, comprising an inter-instance path that connects the first pad to the second pad through a plurality of multiplexers comprising:
a first set of multiplexers that each share a first circuit layout that is the same as the first multiplexer; and
a second set of multiplexers that each share a second circuit layout that is the same as the second multiplexer.

EXAMPLE EMBODIMENT 20. An integrated circuit system comprising:
a receiver with plurality of receiver inputs;
plurality of pads each to receive respective pad signals;
a first plurality of multiplexers coupled to the plurality of pads and each to selectively couple a respective pad of the plurality of pads to a respective receiver input of the plurality of receiver inputs, wherein the first plurality of multiplexers are high-speed multiplexers that have electrical overstress (EOS) protection;
a second plurality of multiplexers each to receive a respective reference voltage each to selectively couple the respective reference voltage to a respective receiver input of the plurality of receiver inputs, wherein the second plurality of multiplexers are slower than the first plurality of multiplexers but maintain EOS protection; and
a third plurality of multiplexers each to receive respective clocks and to selectively couple the respective clocks to respective receiver inputs of the plurality of receiver inputs.

What is claimed is:

1. An integrated circuit system, comprising:
a programmable logic device, comprising:
programmable logic units implementing a user design; and
programmable input/output (IO) circuitry comprising a plurality of receiver instances each comprising:
a first type of multiplexer, wherein the first type of multiplexer is configured to receive a pad input, and the first type of multiplexer is a high-speed multiplexer that has electrical overstress (EOS) protection;
a second type of multiplexer that has EOS protection and is configured to receive a voltage, wherein the second type of multiplexer responds slower than the first type of multiplexer;
a third type of multiplexer that does not have EOS protection and is configured to receive a clock; and
a receiver to selectively receive outputs of the first type of multiplexer, the second type of multiplexer, and the third type of multiplexer at an input of the receiver.

2. The integrated circuit system of claim 1, wherein the programmable IO circuitry comprises a pad multiplexer (padmux) that includes the first type of multiplexer, the second type of multiplexer, and the third type of multiplexer.

3. The integrated circuit system of claim 1, wherein the programmable IO circuitry comprises a reference voltage generator to generate a reference voltage as the voltage.

4. The integrated circuit system of claim 1, wherein the programmable IO circuitry comprises:
a second copy of the first type of multiplexer to receive a second pad input;
a second copy of the second type of multiplexer to receiver a second voltage; and
a second copy of the third type of multiplexer to receive a second clock.

5. The integrated circuit system of claim 4, wherein the receiver comprises a non-inverting input to selectively receive the pad input, the voltage, and the clock.

6. The integrated circuit system of claim 5, wherein the receiver comprises an inverting input to selectively receive the second pad input, the second voltage, and the second clock.

7. The integrated circuit system of claim 6, wherein second pad input is a bar pad input that receives a signal complementary to that received at the pad input.

8. The integrated circuit system of claim 1, wherein the programmable IO circuitry comprises a supply multiplexer (mux) that selectively outputs variable supply voltages based a selected mode.

9. The integrated circuit system of claim 8, wherein the third type of multiplexer is to receive the variable supply voltages as control signals to a transmission gate of the third type of multiplexer.

10. The integrated circuit system of claim 9, wherein the selected mode comprises an indication of whether to use a low power mode or a regular power mode.

11. The integrated circuit system of claim 1, wherein the first type of multiplexer comprises pair of transistors acting as a transmission gate as the only transistors in-line between an input node and an output node of the first type of multiplexer.

12. The integrated circuit system of claim 11, wherein the first type of multiplexer comprises a plurality of EOS protection transistors that provide EOS protection without inhibiting transmission through the transmission gate.

13. The integrated circuit system of claim 12, wherein the plurality of EOS protection transistors comprises a first set of transistors coupled between the input node the first type of multiplexer and gates of the transistors of the transmission gate to protect the transistors of the transmission gate from EOS.

14. The integrated circuit system of claim 13, wherein the plurality of EOS protection transistors comprises a second set of transistors coupled between control signals and gate terminals of the transistors of the transmission gate to manage a voltage at nodes at the gate terminals of the transistors of the transmission gate.

15. The integrated circuit system of claim 14, wherein the plurality of EOS protection transistors comprises a set of leaker transistors coupled to the output node of the first type of multiplexer to limit a voltage on the output node.

16. A programmable input/output (IO) for a programmable logic device, wherein the programmable IO comprises:
a first receiver (RX) instance, comprising:
a receiver;
a first pad input to receive first pad signals from a first pad;
a first clock input to receive a first clock signal;
a first reference voltage input to receive a first reference voltage;
a first multiplexer configured to receive the first pad signals and selectively output the first pad signals to the receiver, wherein the first multiplexer comprise a first transmission gate and first electrical overstress (EOS) protection transistors;
a second multiplexer to receive the first reference voltage and selectively output the first reference voltage to the receiver, wherein the second multiplexer comprises a second transmission gate and second EOS protection transistors, wherein the second multiplexer has a lower bandwidth than the first multiplexer; and
a third multiplexer to receive the first clock signal and selectively output the first clock signal to the receiver.

17. The programmable IO of claim 16, wherein the receiver comprises an inverting input and a non-inverting input, the receiver is to receive the first pad signals, the first clock signal, and the first reference voltage at the non-inverting input, and the first RX instance comprises:
a second pad input to receive second pad signals from a second pad;
a second clock input to receive a second clock signal;
a second reference voltage input to receive a second reference voltage;
a fourth multiplexer configured to receive the second pad signals and selectively output the second pad signals to the inverting input of the receiver, wherein the fourth multiplexer comprises a third transmission gate and third electrical overstress (EOS) protection transistors;
a fifth multiplexer to receive the second reference voltage and selectively output the second reference voltage to the inverting input of the receiver, wherein the fifth multiplexer comprises a fourth transmission gate and fourth EOS protection transistors, wherein the fifth multiplexer has a lower bandwidth than the fourth multiplexer; and
a sixth multiplexer to receive the second clock signal and selectively output the second clock signal to the inverting input of the receiver.

18. The programmable IO of claim 16, comprising a second RX instance comprising:
a second receiver;
a second pad input to receive second pad signals from a second pad;
a second clock input to receive a second clock signal;
a second reference voltage input to receive a second reference voltage;
a fourth multiplexer configured to receive the second pad signals and selectively output the second pad signals to the second receiver, wherein the fourth multiplexer comprises a third transmission gate and third electrical overstress (EOS) protection transistors;
a fifth multiplexer to receive the second reference voltage and selectively output the second reference voltage to the second receiver, wherein the fifth multiplexer comprises a fourth transmission gate and fourth EOS protection transistors, wherein the fifth multiplexer has a lower bandwidth than the fourth multiplexer; and
a sixth multiplexer to receive the second clock signal and selectively output the second clock signal to the second receiver.

19. The programmable IO of claim 18, comprising an inter-instance path that connects the first pad to the second pad through a plurality of multiplexers comprising:
a first set of multiplexers that each share a first circuit layout that is the same as the first multiplexer; and
a second set of multiplexers that each share a second circuit layout that is the same as the second multiplexer.

20. An integrated circuit system comprising:
a receiver with plurality of receiver inputs;
plurality of pads each to receive respective pad signals;
a first plurality of multiplexers coupled to the plurality of pads and each to selectively couple a respective pad of the plurality of pads to a respective receiver input of the plurality of receiver inputs, wherein the first plurality of multiplexers are high-speed multiplexers that have electrical overstress (EOS) protection;
a second plurality of multiplexers each to receive a respective reference voltage each to selectively couple the respective reference voltage to a respective receiver input of the plurality of receiver inputs, wherein the second plurality of multiplexers are slower than the first plurality of multiplexers but maintain EOS protection; and
a third plurality of multiplexers each to receive respective clocks and to selectively couple the respective clocks to respective receiver inputs of the plurality of receiver inputs.
